(19) United States
(12) Patent Application Publication
(10) Pub. No.: US 2026/0206508 A1
(43) Pub. Date: Jul. 16, 2026

(54) Etching Method and Etching Apparatus

(71) Applicant: Tokyo Electron Limited, Tokyo (JP)

(72) Inventors: Nobuhiro TAKAHASHI, Yamanashi (JP); Yusuke IMAI, Yamanashi (JP); Kento SUZUKI, Yamanashi (JP)

(21) Appl. No.: 19/562,917

(22) Filed: Mar. 11, 2026

Related U.S. Application Data
(63) Continuation of application No. PCT/JP2024/030794, filed on Aug. 28, 2024.

(30) Foreign Application Priority Data
Sep. 11, 2023 (JP) 2023-147055

(51) Int. Cl. H10P 50/24; H10P 72/00

(52) U.S. Cl. CPC H10P 50/242; H10P 72/0421

(57) ABSTRACT

An etching method is provided. The method includes: placing a substrate having SiGe or Ge on a surface thereof in a chamber; supplying an etching gas for etching SiGe or Ge to the substrate maintained at a first temperature at which no etching reaction occurs and adsorbing the etching gas onto the surface of the substrate; and changing the temperature of the substrate to a second temperature at which reaction between the SiGe or Ge and the etching gas occurs and etching the SiGe or Ge.

### CROSS-REFERENCE TO RELATED APPLICATIONS

This application is a bypass continuation application of International Application No. PCT/JP2024/030794 having an international filing date of August 28, 2024 and designating the United States, the International Application being based upon and claiming the benefit of priority from Japanese Patent Application No. 2023-147055 filed on September 11, 2023, the entire contents of which are incorporated herein by reference.

### TECHNICAL FIELD

The present disclosure relates to an etching method and an etching apparatus.

### BACKGROUND

Recently, silicon germanium (SiGe) and germanium (Ge) have been attracting attention as semiconductor materials other than silicon (Si). Japanese Laid-open Patent Publication No. 2020-53448 proposes a technique for selectively etching SiGe or Ge relative to Si using a processing gas containing a fluorine-containing gas and a hydrogen-containing gas.

### SUMMARY

The present disclosure provides an etching method and an etching apparatus capable of etching SiGe or Ge with high controllability.

An etching method according to one aspect of the present disclosure comprises: placing a substrate having SiGe or Ge on a surface thereof in a chamber; supplying an etching gas for etching SiGe or Ge to the substrate maintained at a first temperature at which no etching reaction occurs and adsorbing the etching gas onto the surface of the substrate; and changing the temperature of the substrate to a second temperature at which reaction between the SiGe or Ge and the etching gas occurs and etching the SiGe or Ge.

### BRIEF DESCRIPTION OF THE DRAWINGS

FIG. 1 is a flowchart showing a specific example of an etching method according to one embodiment.

FIG. 2 is a cross-sectional view schematically showing an example of the state of a substrate after step ST2 of the etching method according to one embodiment has been performed.

FIG. 3 is a cross-sectional view schematically showing an example of the state of the substrate after step ST3 of the etching method according to one embodiment has been performed.

FIG. 4 is a cross-sectional view schematically showing an example of the state of the substrate after step ST4 of the etching method according to one embodiment has been performed.

FIG. 5 is a timing chart showing a typical example of a process sequence of steps ST2 to ST5 of the etching method according to one embodiment.

FIG. 6 is a cross-sectional view showing an example of the structure of a wafer that is a substrate to which an etching method according to one embodiment is applied.

FIG. 7 is a cross-sectional view showing the state of the wafer having the structure of FIG. 6, in which an SiGe film has been partially etched.

FIG. 8 is a cross-sectional view showing the state of the wafer having the structure of FIG. 6, in which the SiGe film has been completely etched.

FIG. 9 is a cross-sectional view showing an example of an etching apparatus for performing an etching method according to an embodiment.

FIG. 10 is a graph showing the results of an evaluation test.

FIG. 11 is an SEM image showing the results of the evaluation test.

FIG. 12 is an SEM image showing the results of the evaluation test.

FIG. 13 is an SEM image showing the results of the evaluation test.

FIG. 14 is an SEM image showing the results of the evaluation test.

### DETAILED DESCRIPTION

Hereinafter, embodiments will be described with reference to the accompanying drawings.

### <Etching method>

In an etching method according to one embodiment, first, a substrate having SiGe or Ge on the surface thereof is placed in a chamber for performing etching. Then, an etching gas for etching SiGe or Ge is supplied to the substrate maintained at a first temperature at which no etching reaction occurs, and is adsorbed onto the substrate surface. Then, the temperature of the substrate is changed to a second temperature at which the reaction between SiGe or Ge and the etching gas occurs, so that SiGe or Ge is etched. The adsorption of the etching gas onto the substrate surface and the etching may be repeated multiple times.

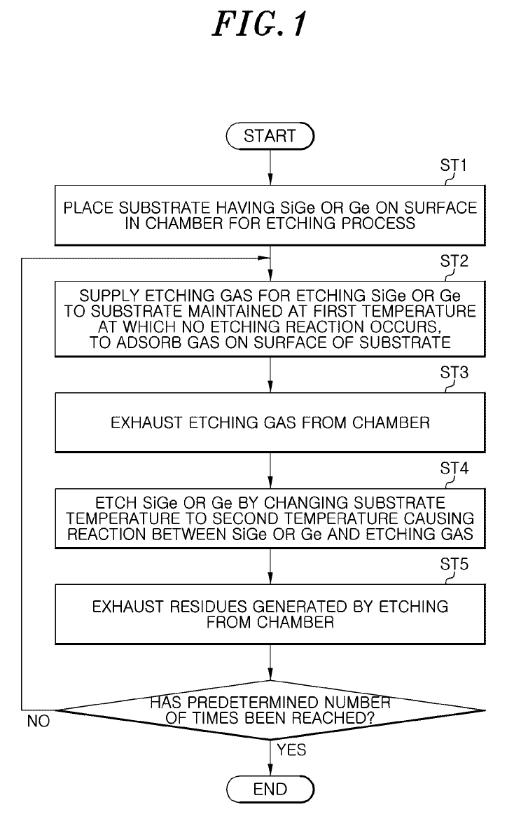

Hereinafter, a specific example of the etching method according to one embodiment will be described with reference to FIG. 1. FIG. 1 is a flowchart showing a specific example of the etching method according to one embodiment.

First, a substrate having SiGe or Ge on the surface thereof is placed in a chamber for performing etching (step ST1).

Next, an etching gas for etching SiGe or Ge is supplied to the substrate maintained at the first temperature at which no etching reaction occurs, and is adsorbed onto the substrate surface (step ST2).

Next, the etching gas is exhausted from the chamber (step ST3).

Next, the substrate temperature is adjusted to the second temperature at which the reaction between SiGe or Ge and the etching gas occurs, so that SiGe or Ge is etched (step ST4).

Next, the residues resulting from the etching are exhausted from the chamber (step ST5).

By performing the above steps ST2 to ST5 once or a predetermined number of times, SiGe or Ge is etched to a desired amount.

Hereinafter, it will be described in detail below.

The ratio of Si and Ge in SiGe is arbitrary, but it is preferable that the ratio of Si is 90 at% or less. The state of SiGe and Ge is not particularly limited, and they may be formed as films by chemical vapor deposition (CVD), for example. The substrate is not particularly limited, but may be a semiconductor wafer (hereinafter, simply referred to as wafer).

The substrate is not particularly limited, but may contain Si in addition to SiGe or Ge, at a portion to be brought into contact with an etching gas during processing. In this case, it is preferable to selectively etch SiGe or Ge relative to Si. The state of Si is also not particularly limited, and it may be either bulk or a film. Si may be doped with B, P, C, As, or the like.

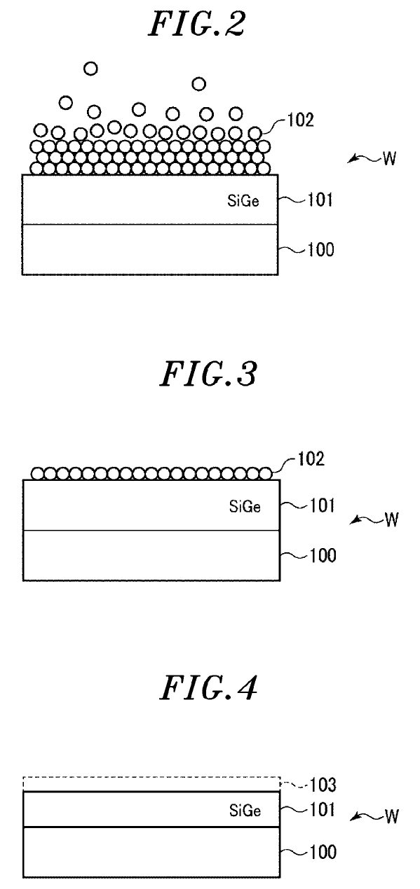

In step ST2, when the processing gas containing the etching gas is supplied to and adsorbed onto the substrate surface, the etching gas is adsorbed until it is saturated on the surface of SiGe or Ge to be etched. For example, as shown in FIG. 2, an etching gas 102 is adsorbed onto the surface of a SiGe film 101 formed on a semiconductor substrate 100 of a substrate W until it is saturated. In this case, the substrate is maintained at the first temperature at which no etching reaction occurs, so that the SiGe film 101 does not react with the adsorbed etching gas 102. In addition to the etching gas, the processing gas may contain an inert gas, such as N₂ gas or Ar gas, as a dilution gas or a carrier gas. The inert gas can also be used as a purge gas.

The etching gas is not particularly limited as long as it can etch SiGe or Ge. For example, a fluorine-containing gas may be used. The fluorine-containing gas is suitable for etching SiGe or Ge with a high selectivity relative to Si. The fluorine-containing gas may be, e.g., ClF₃ gas, F₂ gas, SF₆ gas, and IF₇ gas, and at least one of them may be used.

When a fluorine-containing gas is used as the etching gas, the first temperature can be set to be lower than the boiling point of the etching product to adsorb the etching gas without causing the etching reaction. The etching product is a reaction product of the etching gas and SiGe or Ge, and is a compound containing Ge and F. If the first temperature is too low, the energy required to change the temperature between the first temperature and the second temperature increases, and the time required for the temperature change increases. From the perspective of adsorbing the etching gas and avoiding excessive cooling of the substrate, the first temperature is preferably -40°C or higher and -20°C or lower.

The substrate temperature can be controlled using a temperature control mechanism, such as a cooling mechanism or a heating mechanism, attached to a placing table (susceptor) for placing a substrate thereon. The substrate temperature can be controlled with high precision by attracting the substrate using an electrostatic chuck for electrostatically attracting the substrate.

The pressure used in step ST2 is appropriately set depending on the etching gas to be used. When the etching gas is a fluorine-containing gas, such as F₂ gas, a pressure within a range of 0.01 Torr to 1 Torr (1.33 Pa to 133 Pa) is desirable. Further, the time for step ST2 may be a period of time in which the etching gas can be adsorbed onto the surface of SiGe or Ge to be etched until it is saturated, e.g., 10 to 300 seconds, for example. When the etching gas is a fluorine-containing gas, e.g., F₂ gas, a period of time longer than 30 seconds is desired, as shown in the test results to be described later.

In step ST3, the etching gas is exhausted from the chamber, thereby removing the excess portion of the etching gas 102 adsorbed onto the substrate surface in step ST2. Accordingly, it is possible to control the amount of etching gas adsorbed onto the surface of SiGe or Ge. In the example of FIG. 2, as shown in FIG. 3, the amount of etching gas 102 adsorbed onto the surface of the SiGe film 101 is controlled to, e.g., one atomic layer or one molecular layer. The method for exhausting the etching gas in step ST3 is not particularly limited, and the etching gas may be exhausted by purging the chamber with an inert gas. Further, the etching gas may be exhausted by evacuating the chamber.

In step ST4, in a state where the etching gas is adsorbed onto the surface of SiGe or Ge in step ST3, the substrate temperature is changed from the first temperature to the second temperature, so that SiGe or Ge is etched. In other words, by changing the substrate temperature to the second temperature, the reaction between SiGe or Ge and the adsorbed etching gas occurs. Accordingly, since the etching reaction occurs after the etching gas is adsorbed, SiGe or Ge can be etched with high controllability. Further, by controlling the amount of adsorption of the etching gas in step ST3, the etching amount can be controlled with higher precision. In the example shown in FIG. 3, the amount of etching gas 102 adsorbed onto the surface of the SiGe film 101 is controlled to one atomic layer or one molecular layer. If the etching reaction occurs in that state, as shown in FIG. 4, the SiGe film 101 can be etched with high precision to the amount corresponding to the amount of adsorption of the etching gas. In FIG. 4, a reference numeral 103 indicates the etched portion of the SiGe film 101.

When a fluorine-containing gas is used as the etching gas, the etching reaction can occur by setting the second temperature to be higher than or equal to the boiling point of the etching product. The boiling point includes the sublimation point. The second temperature is higher than the first temperature, and is preferably -20°C or higher.

The substrate temperature can be changed from the first temperature to the second temperature by changing the control temperature of the temperature control mechanism. Instead of changing the control temperature of the temperature control mechanism of the placing table, the temperature control mechanism of a shower head, which is a gas injection part provided to face the placing table, can be used to change the substrate temperature by raising the substrate using lift pins attached to the placing table. The substrate temperature can also be changed by supplying a gas to the substrate or by using plasma generated by a plasma generator.

The pressure used for executing step ST4 is appropriately set depending on the etching gas to be used. When the etching gas is a fluorine-containing gas, such as F₂ gas, a pressure within a range of 0.01 Torr to 3 Torr (1.33 Pa to 400 Pa) is desired. The duration of step ST4 is set to a period of time that allows the adsorbed etching gas to react with SiGe or Ge appropriately. For example, when the etching gas is a fluorine-containing gas, such as F₂ gas, a period of time longer than 30 seconds is desired. When the substrate has a structure in which SiGe or Ge coexists with Si, and SiGe or Ge is etched selectively relative to Si, the duration of step ST4 is set to minimize the etching of Si.

Step ST5 can be performed in any manner that allows etching residues to be removed from the chamber. For example, step ST5 can be executed by evacuating the chamber. The chamber may also be purged with an inert gas and then evacuated.

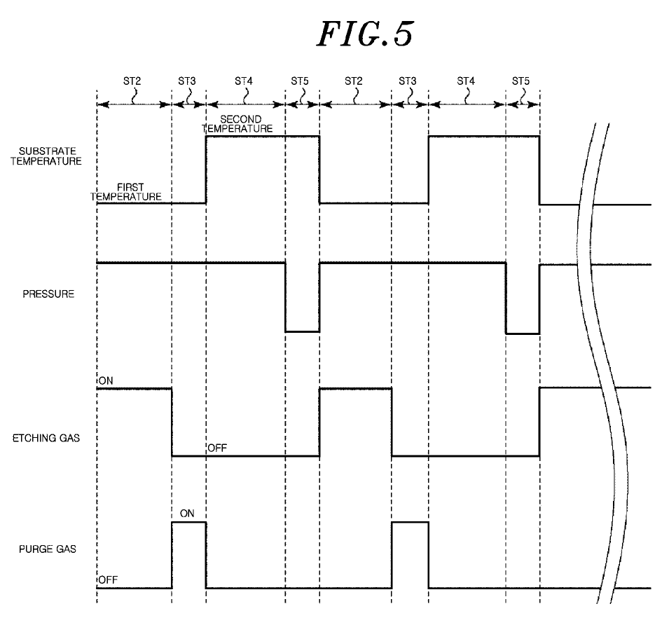

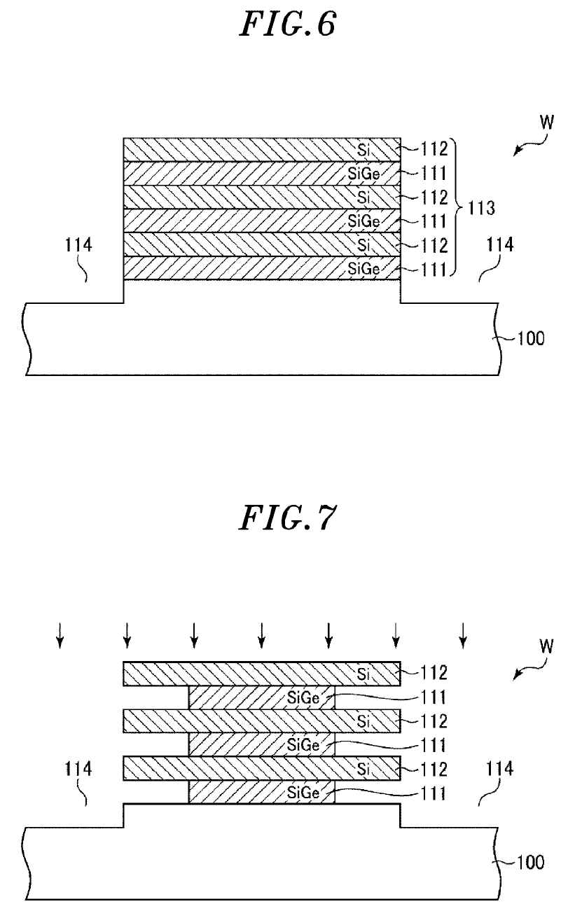

A typical example of a process sequence for steps ST2 to ST5 is shown in the timing chart of FIG. 5. In the process sequence of FIG. 5, in step ST2, the etching gas is supplied (turned ON) to be adsorbed onto the substrate maintained at the first temperature. In step ST3, the etching gas is OFF and the purge gas is ON to purge the chamber. In step ST4, the substrate temperature is raised to the second temperature to make the etching reaction proceed. In step ST5, the chamber is evacuated to remove residues in the chamber.

Next, an application example of the etching method of one embodiment will be described.

FIG. 6 is a cross-sectional view showing an example of the structure of a wafer that is a substrate to which the etching method of one embodiment is applied. The wafer W in FIG. 6 has a laminated (multilayer) structure 113 in which SiGe films 111 and Si films 112 are alternately stacked on the surface of a semiconductor substrate 100 made of Si, for example. A recess 114 is formed in the laminated structure 113 by plasma etching, and the side surfaces of the alternately stacked SiGe films 111 and Si films 112 are exposed in the recess 114.

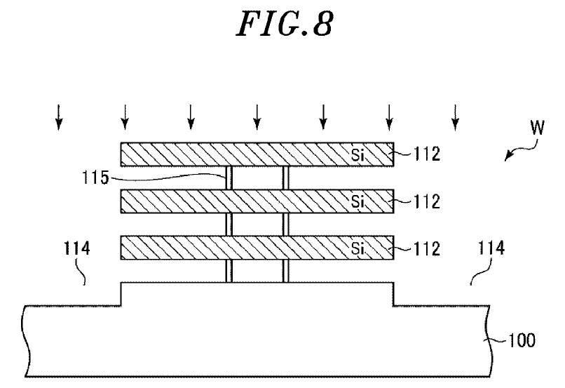

By repeatedly performing steps STST2 to ST5 described above on the wafer W in FIG. 6 using a fluorine-containing gas such as F₂ gas, the SiGe films 111 are side-etched as shown in FIG. 7, whereby the SiGe films 111 are selectively etched relative to the Si films 112. Although FIG. 7 shows that the SiGe films 111 are partially etched, the SiGe films 111 may be completely etched, as shown in FIG. 8. Even after the SiGe films 111 are completely etched, the remaining Si films 112 are supported by support columns 115 made of SiN or the like.

In the present embodiment, after the etching gas is adsorbed onto the substrate surface, the amount of adsorption is controlled, and the substrate temperature is changed from the first temperature to the second temperature to cause the etching reaction. Accordingly, it is possible to etch SiGe or Ge on the substrate surface with high controllability.

In other words, in the present embodiment, the etching reaction proceeds by changing the temperature after the amount of etching gas adsorbed onto the surface of SiGe or Ge is controlled. Therefore, the amount of etching per cycle, which corresponds to the adsorbed etching gas, is very small, thereby enabling the etching to be controlled with high controllability. Further, by performing steps ST2 to ST5 once or multiple times, the etching can be performed to obtain a desired etching amount. Specifically, the roughness can be controlled during etching, and even the control of minute etching amount can be performed. Further, it is also possible to suppress loading effect in dense/sparse patterns and top/bottom loading effect.

### <Etching apparatus>

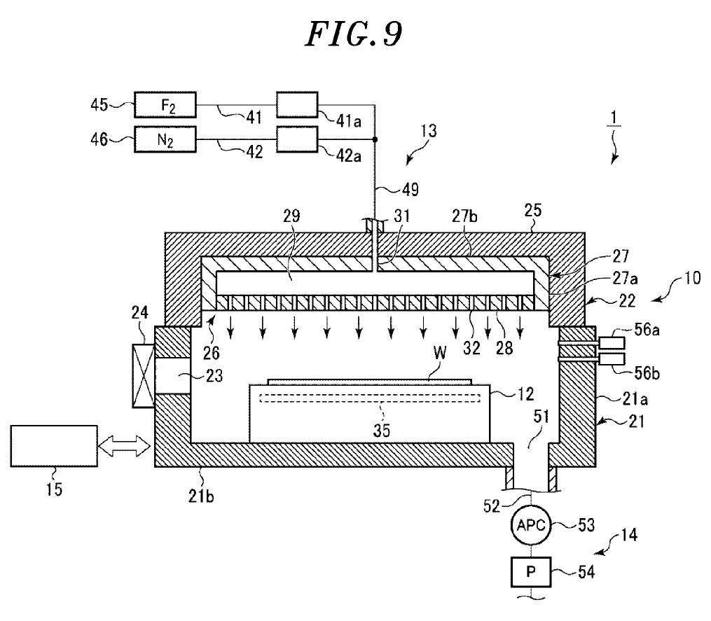

Next, an example of an etching apparatus for performing the etching method according to the embodiment will be described. FIG. 9 is a cross-sectional view of an example of the etching apparatus.

As shown in FIG. 9, an etching apparatus 1 includes a sealed chamber 10. A placing table 12 on which a substrate W is placed in a horizontal state is provided in the chamber 10. The substrate W has a surface portion having SiGe or Ge, and may have the structure shown in FIG. 6, for example. The etching apparatus 1 further includes a gas supply mechanism 13 that supplies an etching gas to the chamber 10, an exhaust mechanism 14 that exhausts the chamber 10, and a controller 15.

The chamber 10 Includes a chamber body 21 and a lid 22. The chamber body 21 has a substantially cylindrical sidewall 21A and a bottom portion 21B, and an open top that is closed by the lid 22. The sidewall 21A and the lid 22 are sealed by a sealing member (not shown), thereby ensuring airtightness ion the chamber 10.

The lid 22 includes a lid member 25 forming the outer portion and a shower head 26 fitted in the lid member 25 and provided to face the placing table 12. The shower head 26 includes a main body 27 having a cylindrical sidewall 27a and an upper wall 27b, and a shower plate 28 attached to the bottom portion of the main body 27. A space 29 is formed between the main body 27 and the shower plate 28.

A gas inlet channel 31 is formed through the lid member 25 and the upper wall 27b of the main body 27 to reach the space 29. The gas inlet channel 31 is connected to a line 49 of the gas supply mechanism 13, which will be described below.

Multiple gas outlet holes 32 are formed at the shower plate 28. A gas introduced into the space 29 via the line 49 and the gas inlet channel 31 is discharged from the gas outlet holes 32 into the space in the chamber 10.

A loading/unloading port 23 for loading and unloading the substrate W is provided at the sidewall 21a. The loading/unloading port 23 can be opened and closed by a gate valve 24.

The placing table 12 has a substantially circular shape in plan view, and is fixed to the bottom portion 21b of the chamber 10. A temperature control mechanism 35 is provided in the placing table 12 to control the temperature of the placing table 12 and control the temperature of the substrate W placed thereon. The temperature control mechanism 35 may include, e.g., a heater and a line through which a low-temperature cooling medium circulates, thereby controlling the temperature of the substrate W. The placing table 12 may also be provided with an electrostatic chuck that electrostatically attracts the substrate W. By attracting the substrate W, the temperature control mechanism 35 can control the temperature of the substrate W with high precision. The placing table 12 includes lift pins (not shown) built therein for transferring the substrate W.

The substrate temperature can be changed from the first temperature to the second temperature by changing the control temperature of the temperature control mechanism 35. Instead of changing the control temperature of the temperature control mechanism 35 for the placing table 12, the temperature control mechanism may be installed in the shower head 26 provided to face the placing table 12, and the substrate temperature may be changed by raising the substrate W using lift pins (not shown) provided at the placing table 12. Further, the temperature of the substrate W can be changed by supplying a gas to the substrate W, or by applying plasma to the substrate using an appropriate plasma generator.

The gas supply mechanism 13 supplies a processing gas containing an etching gas. In this example, F₂ gas that is a fluorine-containing gas is supplied as the etching gas. In addition to the etching gas, an inert gas can also be supplied as a processing gas. In this example, N₂ gas is supplied as an inert gas. The inert gas is used as a carrier gas, a dilution gas, and a purge gas. Specifically, the gas supply mechanism 13 includes an F₂ gas supply source 45 that supplies F₂ gas as an etching gas, and an N₂ gas supply source 46 that supplies N₂ gas as an inert gas. They are connected to one end of an F₂ gas supply line 41 and an N₂ gas supply line 42, respectively. The other ends of the F₂ gas supply line 41 and the N₂ gas supply line 42 are connected to a common line 49 that is connected to the gas inlet channel 31 described above. The F₂ gas supply line 41 and the N₂ gas supply line 42 are provided with flow rate controllers 41a and 42a that control opening and closing of the flow paths and control the flow rates, respectively. The flow rate controllers 41a and 42a include, e.g., an on-off valve and a flow rate controller such as a mass flow controller.

Therefore, F₂ gas as an etching gas and N₂ gas as an inert gas are supplied from the gas supply sources 45 and 46 through the lines 41, 42, and 49 into the shower head 26 and then discharged into the chamber 10 through the gas outlet holes 32 in the shower plate 28.

The exhaust mechanism 14 includes an exhaust line 52 connected to an exhaust port 51 formed at the bottom portion 21b of the chamber 10, and further includes an automatic pressure control valve (APC) 53 for controlling the pressure in the chamber 10 and a vacuum pump 54 for evacuating the chamber 10, which are provided in the exhaust line 52.

Two capacitance manometers 56a and 56b, one for high pressure and the other for low pressure, are provided on the sidewall of the chamber 10 to be inserted into the chamber 10, and serve as pressure gauges for measuring the pressure in the chamber 10. The opening degree of the automatic pressure control valve (APC) 53 is adjusted based on the values detected by the capacitance manometers 56a and 56b, thereby controlling the pressure in the chamber 10.

The controller 15 is typically a computer, and includes a main controller having a CPU that controls individual components of the etching apparatus 1. The controller 15 further includes an input device (keyboard, mouse, or the like), an output device (printer, or the like), a display device (display, or the like), and a storage device (storage medium) that are connected to the main controller. The main controller of the controller 15 controls the operation of the etching apparatus 1 based on a process recipe stored, e.g., in a storage medium built into the storage device or a storage medium set in the storage device.

In the etching apparatus 1 configured as described above, a substrate W is loaded into the chamber 10 and placed on the placing table 12. The temperature of the placing table 12 is controlled by the temperature control mechanism 35, and the temperature of the substrate W is set to the first temperature at which no etching reaction occurs. The first temperature is set by the temperature control mechanism 35 for the placing table 12 to a temperature lower than the boiling point of the etching product, preferably between -40°C and -20°C. The pressure in the chamber 10 is controlled within a range of 0.01 Torr to 1 Torr (1.33 Pa to 133 Pa), for example.

In this state, the processing gas containing F₂ gas as a fluorine-containing gas is supplied as an etching gas into the chamber 10. As a result, F₂ gas is adsorbed onto the surface of the substrate W maintained at the first temperature. In addition to F₂ gas, N₂ gas as an inert gas may also be supplied as the processing gas. The F₂ gas adsorption process is continued until the surface of SiGe or Ge to be etched on the surface of the substrate W is saturated. The time for this process is preferably longer than 30 seconds.

Next, the supply of F₂ gas is stopped, and N₂ gas, for example, is supplied into the chamber 10 to purge the chamber 10. Accordingly, excess F₂ gas not adsorbed onto the substrate W is discharged (purged) from the chamber 10, thereby controlling the adsorption amount of F₂ gas.

Next, the temperature of the substrate W is increased from the first temperature to the second temperature to cause the reaction between SiGe or Ge on the substrate W and the adsorbed etching gas and make the etching of SiGe or Ge proceed. The second temperature is set to a temperature higher than or equal to the boiling point of the etching product, preferably -20°C or higher. The pressure in the chamber 10 is controlled to be within a range of 0.01 Torr to 3 Torr (1.33 Pa to 400 Pa), for example.

In this case, the substrate temperature can be changed from the first temperature to the second temperature by changing the control temperature of the temperature adjustment mechanism 35, as described above. Alternatively, as described above, the temperature of the substrate W may be changed without changing the control temperature of the temperature control mechanism 35 by raising the substrate W using lift pins, or by supplying a gas to the substrate W, or using plasma. In this case, the etching time is preferably longer than 30 seconds. As shown in FIG. 6, when the substrate W has a structure in which SiGe or Ge and Si coexist, the etching time is set to minimize the etching of Si.

Next, the chamber 10 is evacuated by the exhaust mechanism 14, and residues resulting from the etching are removed from the chamber.

The above process is performed once or a predetermined number of times to etch SiGe or Ge to a desired amount. After the etching is completed, the substrate W is unloaded from the chamber 10.

In the etching apparatus 1, the processing is performed by changing the temperature of the substrate W in a single chamber 10. Therefore, in the case of performing processing by changing the temperature of the substrate W using the temperature control mechanism 35, if the second temperature is too high, a long period of time is required until the substrate W is ready to be processed at the first temperature in processing a single substrate W by repeating steps ST2 to ST5 or in sequentially loading multiple substrates W into the chamber 10 and processing them. In other words, after the substrate W is processed at the second temperature, a long period of time is required to cool individual components in the chamber 10 so that the substrate W can be processed at the first temperature. In order to vaporize the etching products while preventing a decrease in throughput due to the long cooling time, the second temperature described above is preferably set to be lower than or equal to, e.g., room temperature, more specifically, 5°C or below. Therefore, the second temperature is set to, e.g., -20°C to 5°C. The above-described room temperature is the temperature of the clean room in which the etching apparatus 1 is located, which is, e.g., 24°C.

Further, the first temperature and the second temperature need to have a slightly margin relative to the boiling point of the etching product. For example, the first temperature may be set to be lower than the boiling point by 1°C or less, and the second temperature may be set to be higher than the boiling point by 1°C or less (hence, the difference between the first temperature and the second temperature is set to 2°C or less). By setting the first temperature and the second temperature near the boiling point of the etching products, rapid temperature control between the first temperature and the second temperature can be realized.

In this manner, the first temperature and the second temperature can be set based on the boiling point of the etching products. Regarding the boiling point, when the substance of the etching products produced by the reaction is known, the boiling point can be set to the boiling point of the substance at the pressure in the chamber 10 when the substrate W is heated to the second temperature. Even if the substance of the etching products is unknown, the boiling point can be determined by conducting a preliminary test before the substrate W is processed in the etching apparatus 1. In the preliminary test, the pressure in the chamber 10 is set to the pressure at the time of heating the substrate W to the second temperature during actual processing, and the substrate W that has been sufficiently cooled and supplied with an etching gas is heated to the second temperature to cause the etching reaction. The temperature at which the occurrence of the etching reaction is recognized can be considered as the boiling point.

### <Another example of etching apparatus>

Hereinafter, an etching apparatus 1A, which is another example of the etching apparatus, will be described. The etching apparatus 1A includes a first module that executes steps ST2 and ST3, and a second module that executes steps ST4 and ST5. The first module has the same configuration as that of the etching apparatus 1, and the second module has the same configuration as that of the etching apparatus 1 except that no etching gas is supplied to the first module. Therefore, the etching apparatus 1A separately includes the chamber 10 for processing the substrate W at the first temperature and the chamber 10 for processing the substrate W at the second temperature.

The etching apparatus 1A further includes a transfer path for the substrate W, which connects the chamber 10 of the first module and the chamber 10 of the second module to create a vacuum atmosphere, and a transfer mechanism capable of moving along the transfer path. The substrate W is repeatedly transferred back and forth between the chambers 10 by the transfer mechanism, thereby repeatedly performing a cycle of steps ST2 to ST5. In this manner, the apparatus may have a configuration in which it is not necessary to change the temperature of the substrate W between the first temperature and the second temperature in a single chamber 10. Due to the apparatus configuration described above, in the etching apparatus 1A, similarly to the etching apparatus 1, a vacuum atmosphere around the substrate W can be maintained during the repetition of the cycle. The evacuation in step ST5 is performed by creating a vacuum atmosphere around the substrate W in steps ST2 to ST5. The evacuation in step ST5 is performed by evacuating the chamber 10 such that an atmosphere with a higher degree of vacuum is crea ted around the substrate W compared to steps ST2 to ST4.

### <Other examples>

For example, after step ST2 in which the etching gas is adsorbed onto the substrate W at the first temperature is executed, the etching may be performed by changing the temperature of the substrate W to the second temperature in step ST4 without executing step ST3 in which the excessive etching gas that is not adsorbed onto the surface of the substrate W is removed by purging or evacuation. The amount of etching gas supplied to the chamber 10 is predetermined to an appropriate amount by executing tests such that the adsorption onto the surface of the SiGe film is saturated and the variation in the adsorption amount at various portions of the surface is minimized, for example. However, it is effective to execute step ST3 in order to more reliably suppress variation in the adsorption amount and suppress variation in the etching amount at various portions of the surface of the SiGe film.

### <Other applications>

The embodiments have been described above, but it should be understood that the embodiments disclosed herein are illustrative in all respects and not restrictive. The above embodiments may be omitted, substituted, or modified in various forms without departing from the scope and spirit of the appended claims.

For example, the substrate structure shown in FIG. 6 is merely an example, and any substrate having SiGe or Ge on the surface thereof is applicable. Further, the structure of the etching apparatus described above is merely an example, and apparatuses with various configurations can be used. Although a case where a semiconductor wafer is used as the substrate has been described, the substrate is not limited to a semiconductor wafer, and may be other substrates, such as a flat panel display (FPD) substrate represented by a liquid crystal display (LCD) substrate, or a ceramic substrate.

### [Evaluation Tests]

Hereinafter, the evaluation tests conducted on the etching method of the present disclosure will be described.

### <Evaluation Test 1>

In Evaluation Test 1, the etching process of the present disclosure was performed using the etching apparatus 1A on multiple wafers having SiGe films formed on the flat surfaces thereof, and the etching amounts of the SiGe films were measured. The etching process was performed under different combinations of the number of cycles of steps ST2 to ST5 (hereinafter, referred to as the number of cycles) and the duration of step ST2 (i.e., the etching gas supply time) for each wafer.

In Evaluation Test 1-1, the etching gas supply time was set to 30 seconds, and the number of cycles was set to 1, 2, or 5. Further, the first temperature of the wafer in steps ST2 and ST3 was set within the desired range described in the above-described embodiment. In step ST3, the chamber 10 was evacuated for 120 seconds in a state where the wafer was placed on the placing table 12, and a mixture of N₂ gas and Ar gas was supplied as a purge gas into the chamber 10 for 60 seconds out of 120 seconds. The total duration of steps ST4 and ST5 was set to 300 seconds, and the wafer temperature in ST4 and ST5 was set to 190°C. Heating the wafer to a temperature higher than that exemplified in the embodiment is intended to ensure that etching products are reliably removed from the wafer, for the purpose of accurately verifying the effects of differences in the etching gas supply time between Evaluation Tests 1-1 to 1-4 (Evaluation Tests 1-2 to 1-4 will be described later).

In Evaluation Tests 1-2 and 1-3, the etching gas supply time was set to 90 seconds. The number of cycles was set to 1, 2, 4, or 8 in Evaluation Test 1-2, and 1, 2, or 5 in Evaluation Test 1-3. In Evaluation Test 1-4, the etching gas supply time was set to 120 seconds, and the number of cycles was set to 1, 2, or 5. Other test conditions for Evaluation Tests 1-2 to 1-4 were the same as those for Evaluation Test 1-1.

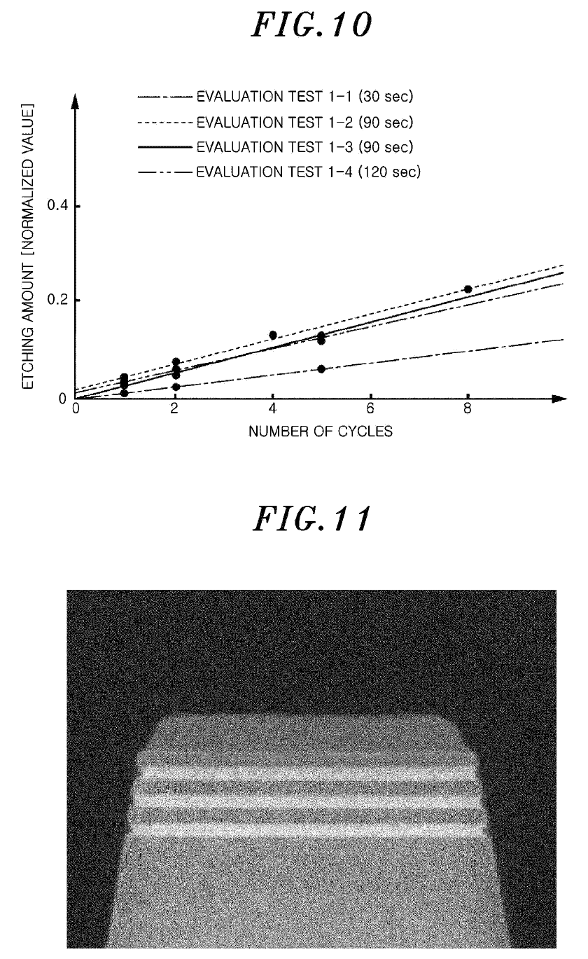

FIG. 10 is a graph showing the results of Evaluation Test 1, illustrating the change in the etching amount with respect to the number of cycles. The vertical axis of the graph represents the normalized value obtained by dividing the measured etching amount by a predetermined value, and the horizontal axis represents the number of cycles. The graph plots the measurement results of Evaluation Tests 1-1 to 1-4, and displays the approximate straight lines calculated from the measurement results for Evaluation Tests 1-1 to 1-4 using different line types. As clearly seen from the graph, the etching amounts in Evaluation Tests 1-1 to 1-4 generally increase in proportion to the number of cycles. Further, in Evaluation Tests 1-1 to 1-4, the unnormalized etching amount for a single cycle was approximately 1 Å. These results show that the etching method of the present disclosure enables the SiGe film to be etched by an extremely small amount and allows the etching amount to be adjusted by the number of cycles.

Further, the approximate straight lines in Evaluation Tests 1-2 to 1-4 are hardly different. In other words, the relationship between the number of cycles and the amount of etching is generally consistent. However, the inclination of the approximate line in Evaluation Test 1-1 is less than those in Evaluation Tests 1-2 to 1-4. From the above, in Evaluation Test 1-1 in which the etching gas supply time was 30 seconds, it is presumed that a part of the surface of the SiGe film where the adsorption of the etching gas was not saturated was exposed without being covered by the etching gas. On the other hand, in Evaluation Tests 1-2 to 1-4 in which the etching gas supply time was 90 seconds or longer, it is presumed that the etching gas was adsorbed and coated onto the entire surface of the SiGe film where the adsorption was saturated. If the adsorption is not saturated, the etching amount may vary at different parts of the film to be etched. Therefore, it is clear from Evaluation Test 1 that the etching gas supply time is preferably longer than 30 seconds, and more preferably longer than or equal to 90 seconds.

Evaluation Test 2

In Evaluation Test 2, a substrate having a laminated structure in which SiGe films and Si films are alternately laminated on a surface as shown in FIG. 6 was prepared, and the test was executed. In the laminated structure, the SiGe films spaced apart from each other were formed in three layers, and the upper and lower sides of each SiGe film are in contact with the Si film. Further, the side surface of each SiGe film is formed generally flat and generally perpendicular to the plane direction of the substrate. The substrate was subjected to the etching process of the present disclosure and the etching process of the comparative example to be described below, and SEM images captured before and after the etching process were compared. Specifically, the SEM images were used to verify the etching differences between the SiGe films and the rectangularity of recesses formed by etching the SiGe films in the respective layers. Further, the lateral etching amounts at different height positions in the respective SiGe films were measured, and the variation thereof was calculated.

Regarding the high rectangularity (vertical profile) of the recesses, it is assumed that the recesses are formed such that the side surface of one SiGe film is perpendicular to the bottom surface of a Si film located above the SiGe film and the upper surface of a Si film located below the SiGe film. If such a recess is used as a reference recess, the high rectangularity indicates that the shape of the actually formed recess approximates the shape of the reference recess, which also means that etching uniformity in the height direction of the side surface of the SiGe film is high. Therefore, the high rectangularity is required.

In Evaluation Test 2-1, the etching in the comparative example was performed. Unlike the etching of the present disclosure, the etching in the comparative example was performed by setting the temperature of the substrate to a relatively high temperature such that the etching gas reacts with the SiGe film during the supply of the etching gas in step ST2 to generate etching products. In other words, the etching gas was supplied at a temperature higher than the range exemplified as the first temperature. In Evaluation Test 2-2, the etching described in FIG. 1 was performed. The processing conditions, except the substrate temperature, were the same between Evaluation Tests 2-1 and 2-2.

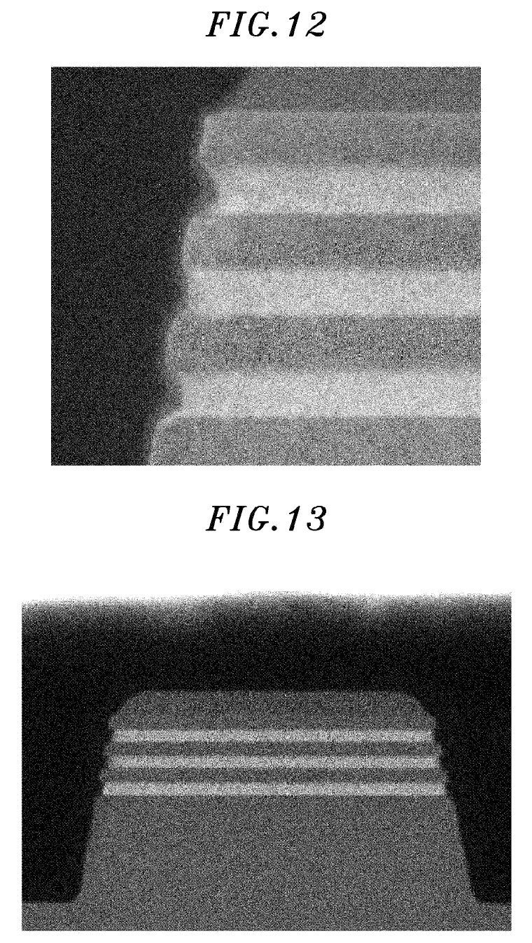

FIGS. 11 and 12 are SEM images of the substrate after etching in Evaluation Test 2-1, and FIG. 12 shows an enlarged portion of the image in FIG. 11. As shown in the images, the side surfaces of the SiGe films were etched more extensively at the central portion in the lamination direction (the thickness direction of the substrate) than at the other portions, and the rectangularity described above was not high. Further, the etching amount of the SiGe film in the second layer was less than the etching amounts of the SiGe films in the first and third layers.

The normalized value of the average etching amount was 1.0. Regarding the variation in the calculated etching amounts, the normalized value of 3σ (unit: nm) was 1.76, and 3σ% was 75.6%. Further, 3σ (unit: nm) = 3×σ (σ being the standard deviation of the etching amount). Further, 3σ% = 3σ (unit: nm)/average etching amount × 100. Therefore, as the normalized value of 3σ (unit: nm) and the value of 3σ% decrease, the variation in the etching amount decreases.

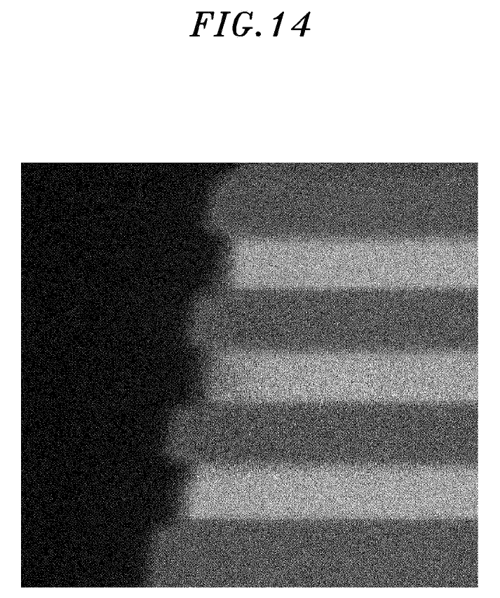

FIGS. 13 and 14 are SEM images of the substrate after etching in Evaluation Test 2-2, and FIG. 14 shows an enlarged portion of the image in FIG. 13. As shown in the images, the side surfaces of the SiGe films were relatively flat, so that the rectangularity described above was good. Further, the etching amounts of the SiGe films in the first to third layers were generally uniform. The normalized value of the average etching amount was 1.04. Regarding the variation in the calculated etching amounts, the normalized value of 3σ (unit: nm) was 0.3, and 3σ% was 27.5%.

As described above, when the etching was performed such that the average etching amount became approximately the same between Evaluation Tests 2-1 and 2-2, Evaluation Test 2-2 demonstrated that the variation in the etching amount was suppressed in the surface of the same SiGe film and in the SiGe films having different heights. Further, Evaluation Test 2-2 demonstrated a higher degree of rectangularity in the space formed by etching, and also demonstrated that the loading (difference in etching rate) between the film formed on the upper side of the substrate (top) and the film formed on the lower side of the substrate (bottom) was suppressed. It is considered that, in Evaluation Test 2-2 showing the above results, the reaction proceeded in a state where the etching gas remained uniformly on the surface of the SiGe film as described in FIGS. 2 to 4 and, thus, the etching amount in one cycle was uniform at different portions. Further, since it is expected that the reaction proceeded as shown in FIGS. 2 to 4, it is estimated that the etching method of the present disclosure can suppress loading and allow different portions to be etched uniformly, even if the film to be etched forms a pattern and the density of the pattern varies across the substrate.

1. An etching method comprising placing a substrate having SiGe or Ge on a surface thereof in a chamber; supplying an etching gas for etching SiGe or Ge to the substrate maintained at a first temperature at which no etching reaction occurs and adsorbing the etching gas onto the surface of the substrate; and changing the temperature of the substrate to a second temperature at which reaction between the SiGe or Ge and the etching gas occurs and etching the SiGe or Ge.

2. The etching method of claim 1, wherein the adsorption of the etching gas onto the surface of the substrate and the etching are repeated multiple times.

3. The etching method of claim 1, further comprising: exhausting the etching gas from the chamber after the adsorption of the etching gas onto the surface of the substrate.

4. The etching method of claim 3, wherein the exhaust of the etching gas from the chamber is achieved by purging the chamber with an inert gas.

5. The etching method of claim 1, further comprising, after the etching: evacuating residues generated by the etching from the chamber.

6. The etching method of claim 5, wherein the evacuation of the residues from the chamber is performed by evacuating the chamber.

7. The etching method of claim 1, wherein the substrate contains Si at a portion to be brought into contact with the etching gas during processing, and the SiGe or Ge is selectively etched relative to the Si.

8. The etching method of claim 7, wherein the SiGe or Ge is a SiGe film or a Ge film, and the Si is a Si film.

9. The etching method of claim 8, wherein the substrate has a laminated structure in which the SiGe film and the Si film are alternately stacked on a surface thereof.

10. The etching method of claim 7, wherein the etching gas is a fluorine-containing gas.

11. The etching method of claim 10, wherein the fluorine-containing gas is at least one of ClF₃ gas, F₂ gas, SF₆ gas, or IF₇ gas.

12. The etching method of claim 10, wherein when a fluorine-containing gas is used as the etching gas, the first temperature is -20°C or lower, and the second temperature is higher than the first temperature.

13. The etching method of claim 12, wherein the second temperature is room temperature or lower.

14. The etching method of claim 1, wherein when the etching gas is adsorbed onto the surface of the substrate, an inert gas is supplied to the substrate together with the etching gas.

15. An etching apparatus comprising: a chamber accommodating a substrate having SiGe or Ge on a surface thereof; a placing table configured to place a substrate thereon in the chamber; a gas supply unit configured to supply an etching gas into the chamber; an exhaust unit configured to exhaust the chamber; a temperature control unit configured to control a temperature of the substrate on the placing table; and a controller; wherein the controller controls the gas supply unit, the exhaust unit, and the temperature control unit to perform the etching method described in claim 1.
